(19) United States
(12) Patent Application Publication
(10) Pub. No.: US 2024/0234469 A1
(43) Pub. Date: Jul. 11, 2024

(54) IMAGE SENSING DEVICE AND METHOD FOR MANUFACTURING THE SAME

(71) Applicant: SK hynix Inc., Icheon-si (KR)

(72) Inventor: Byoung Gyu KIM, Icheon-si (KR)

(21) Appl. No.: 18/357,046

(22) Filed: Jul. 21, 2023

(30) Foreign Application Priority Data
Jan. 5, 2023 (KR) 10-2023-0001488

(51) Int. Cl. H01L 27/146

(52) U.S. Cl. CPC H01L 27/14636; H01L 27/14683; H01L 21/02181

(57) ABSTRACT

Disclosed are image sensing devices capable of enhancing field effect passivation (FEP) and controlling dark characteristics. In some implementations, an image sensing device includes a substrate, a first dielectric layer formed over the substrate, and a field effect passivation layer formed over the first dielectric layer.

### PRIORITY CLAIM AND CROSS REFERENCE TO RELATED APPLICATION

This patent document claims the priority and benefits of Korean Patent Application No. 10-2023-0001488, filed on Jan. 5, 2023, which is incorporated by reference in its entirety as part of the disclosure of this patent document.

### TECHNICAL FIELD

Various embodiments of the disclosed technology relate to an image sensing device and a method for manufacturing the image sensing device.

### BACKGROUND

An image sensing device refers to a semiconductor device that captures and converts an optical image to electrical signals. With the development of computer and communication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensors and complementary metal oxide semiconductor (CMOS) image sensors (CISs). CCD image sensors have advantages over CMOS image sensors in terms of noise characteristics and image quality. However, CMOS image sensors are now widely used due to certain advantages over CCD image sensors, including, e.g., a simple driving scheme and various scanning mechanisms. In addition, CMOS image sensors and signal processing circuitry can be integrated into a single chip using CMOS process technology, making it possible to miniaturize electronic devices while achieving low power consumption and low manufacturing cost. Such characteristics of CMOS image sensors make these sensors better suited for implementations in mobile devices.

### SUMMARY

The disclosed technology can be implemented in some embodiments to provide an image sensing device capable of enhancing field effect passivation (FEP) and controlling dark characteristics and a method for manufacturing the same.

In an embodiment, an image sensing device includes a substrate; a first dielectric layer formed over the substrate; and a field effect passivation layer formed over the first dielectric layer.

The field effect passivation layer may include a first high-k dielectric layer formed over the first dielectric layer and having a first dielectric constant higher thana dielectric constant of the first dielectric layer; a second high-k dielectric layer having a second dielectric constant higher than the dielectric constant of the first dielectric layer; and a second dielectric layer formed between the first high-k dielectric layer and the second high-k dielectric layer.

The first dielectric layer may include SiO2.

The first high-k dielectric layer may include Al2O3.

The second high-k dielectric layer may include HfO2.

The second dielectric layer may include SiO2.

Each of the first dielectric layer and the second dielectric layer may have a thickness ranging from 20 Å to 100 Å.

In an embodiment, an image sensing device includes a substrate; a first dielectric layer formed over the substrate; a first high-k dielectric layer formed over the first dielectric layer and having a first dielectric constant higher thana dielectric constant of the first dielectric layer; a second dielectric layer formed rover the first high-k dielectric layer; a second high-k dielectric layer formed over the second dielectric layer and having a second dielectric constant higher than the dielectric constant of the first dielectric layer; a third insulating layer formed over the second high-k dielectric layer; and a third dielectric layer formed on the third insulating layer and having a third dielectric constant higher than the reference dielectric constant.

Each of the first dielectric layer, the second dielectric layer, and the third insulating layer may include SiO2.

The first high-k dielectric layer may include Al2O3.

The second high-k dielectric layer may include HfO2.

The third dielectric layer may include ZrO2.

Each of the first dielectric layer, the second dielectric layer, and the third insulating layer may have a thickness ranging from 20 Å to 100 Å.

In an embodiment, a method of manufacturing an image sensing device includes forming a first dielectric layer over a substrate; forming a first high-k dielectric layer having a first dielectric constant higher than a dielectric constant of the first dielectric layer over the first dielectric layer; forming a second dielectric layer over the first high-k dielectric layer; and forming a second high-k dielectric layer having a second dielectric constant higher than the dielectric constant of the first dielectric layer over the second dielectric layer.

Each of the insulating layer and the second dielectric layer may include SiO2.

The first high-k dielectric layer may include Al2O3.

The second high-k dielectric layer may include HfO2.

In an embodiment, an image sensing device may include a substrate, a field effect passivation layer disposed over the substrate and configured to establish a surface electric field that repels carriers to reduce a recombination of carriers, and a first interlayer layer disposed between the substrate and the field effect passivation layer and configured to generate one or more dipoles at a boundary between the field effect passivation layer and the first interlayer layer.

In an embodiment, an image sensing device may include a substrate, a first dielectric layer disposed over the substrate and having a first dielectric constant higher than a reference dielectric constant, a first interlayer layer disposed between the substrate and the field effect passivation layer and configured to generate one or more dipoles at a boundary between the first interlayer layer and the first dielectric layer, a second dielectric layer disposed over the first dielectric layer and having a second dielectric constant higher than the reference dielectric constant, a second interlayer layer disposed between the first interlayer layer and the second dielectric layer and configured to generate one or more dipoles at either a boundary between the first dielectric layer and the second interlayer layer, or a boundary between the second dielectric layer and the second interlayer layer, a third dielectric layer disposed over the second dielectric layer and having a third dielectric constant higher than the reference dielectric constant, and a third interlayer layer disposed between the second dielectric layer and the third dielectric layer and configured to generate one or more dipoles at a boundary including at least one of a boundary between the second dielectric layer and the third interlayer layer or a boundary between the third dielectric layer and the third interlayer layer.

In an embodiment, a method of manufacturing an image sensing device may include forming a first interlayer layer on a substrate, forming, on the first interlayer layer, a first dielectric layer having a first dielectric constant higher than a reference dielectric constant, forming a second interlayer layer on the first dielectric layer, and forming, on the second interlayer layer, a second dielectric layer having a second dielectric constant higher than the reference dielectric constant, wherein the first interlayer layer is configured to generate one or more dipoles at a boundary between the first interlayer layer and the first dielectric layer, and the second interlayer layer is configured to generate one or more dipoles at either (1) a boundary between the first dielectric layer and the second interlayer layer or (2) a boundary between the second dielectric layer and the second interlayer layer.

### BRIEF DESCRIPTION OF THE DRAWINGS

FIG. 1 is a block diagram of an image sensing device based on an embodiment.

FIG. 2 illustrates an example of a portion of a layered structure of pixels included in the pixel array shown in FIG. 1.

FIGS. 3 to 6 show a process of forming the stacked structure of FIG. 2.

FIGS. 7 and 8 illustrate an example of a portion of a layered structure of a pixel included in the pixel array shown in FIG. 1.

FIG. 9 is a diagram showing rectangular areas each including Vfb measurement values for each film stack.

FIG. 10 is a diagram showing a hot pixel reduction effect based on an embodiment.

FIG. 11 is a flowchart of a method of manufacturing an image sensing device including the stacked structure of FIG. 2.

### DETAILED DESCRIPTION

Features, and certain advantages in connection with specific implementations of the disclosed technology disclosed in this patent document are described by example embodiments with reference to the accompanying drawings.

In some implementations, image sensors such as CMOS image sensors (CISs) include a deep trench isolation structure to prevent cross talk between image sensing pixels. However, such deep trench isolation structure may suffer severe deterioration in dark characteristics due to trap sites of a surface created when etching Si.

Since a decrease in the area of a photo diode (PD) makes it difficult to secure full well capacity (FWC) due to a decrease in the pixel size of CISs, the doping depth of the PD increases and the depth of the deep trench isolation structure for isolation between pixels increases, so that the number of trap sites that cause deterioration in dark characteristics may increase, making it difficult to control the dark characteristics.

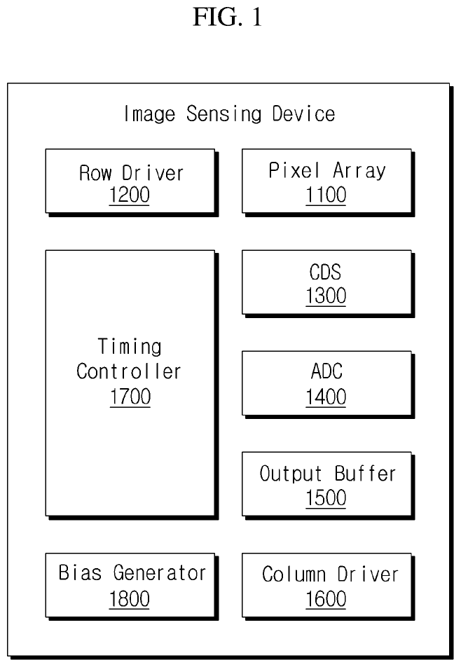

FIG. 1 is a block diagram of an image sensing device based on an embodiment.

Referring to FIG. 1, an image sensing device based on an embodiment may include a pixel array 1100, a row driver 1200, a correlated double sampler (CDS) 1300, and an analog-to-digital converter (ADC) 1400, an output buffer 1500, a column driver 1600, a timing controller 1700, and a bias generator 1800. Here, the components of the image sensing device are merely exemplary, and at least some components may be added or omitted as needed.

The pixel array 1100 may include a plurality of pixels arranged in a plurality of rows and a plurality of columns. In an embodiment, the plurality of pixels may be arranged in a two-dimensional pixel array including rows and columns. In another embodiment, a plurality of unit image pixels may be arranged in a three-dimensional pixel array. A plurality of pixels may convert an optical signal into an electrical signal on a pixel basis or on a pixel group basis, and pixels (e.g., image sensing pixels) in a pixel group may share at least a specific internal circuit. The pixel array 1100 may receive a driving signal including a row selection signal, a pixel reset signal, a transmission signal and others from the row driver 1200, and a corresponding pixel of the pixel array 1100 may be enabled by the driving signal to perform operations corresponding to the row selection signal, the pixel reset signal and the transmission signal.

The row driver 1200 may enable the pixel array 1100 to perform specific operations on pixels included in a corresponding row based on commands and control signals supplied by the timing controller 1700. In one embodiment, the row driver 1200 may select at least one pixel arranged in at least one row of the pixel array 1100. The row driver 1200 may generate a row selection signal to select at least one row out of a plurality of rows. The row driver 1200 may sequentially enable pixel reset signals and transmission signals for pixels corresponding to at least one row selected. Accordingly, analog reference signals and image signals generated by the pixels of the selected row may be sequentially transmitted to the correlated double sampler 1300. Here, the reference signal may be an electrical signal that is provided to the correlated double sampler 1300 when a sensing node (e.g., floating diffusion node) for the pixel is reset, and the image signal may be an electrical signal that is provided to the correlated double sampler 1300 when photoelectric charge generated by the pixel is accumulated in the sensing node. The reference signal may represent reset noise that is generated in the pixel and the image signal may represent the intensity of incident light. In some implementations, the reference signal and the image signal may be collectively referred to as a pixel signal.

CMOS image sensors may use correlated double sampling to eliminate undesired offset values of pixels, such as fixed pattern noise by sampling the pixel signal twice and removing a difference between two samples. For example, the correlated double sampling may remove an unwanted offset value by comparing pixel output voltages obtained before and after the photoelectric charge generated by the incident light is accumulated in the sensing node, so that the pixel output voltage based only on the incident light may be measured. In an embodiment, the correlated double sampler 1300 may sequentially sample and hold the reference signal and the image signal provided to each of a plurality of column lines from the pixel array 1100. That is, the correlated double sampler 1300 may sample and hold the level of the reference signal and the level of the image signal corresponding to each of the columns of the pixel array 1100.

The correlated double sampler 1300 may transfer the reference signal and the image signal of each column to the ADC 1400 as correlated double sampling signals based on a control signal from the timing controller 1700.

The ADC 1400 may convert the correlated double sampling signal for each column output from the correlated double sampler 1300 into a digital signal and output the digital signal. In one embodiment, the ADC 1400 may be implemented with a ramp-compare type ADC. The ramp-compare type ADC may include a comparison circuit that compares a ramp signal that rises or falls with time and an analog pixel signal, and a counter that performs a counting operation. In an example, the counter may perform the counting operation until the ramp signal matches an analog pixel signal. In another example, the counter may count the number of crossing points of the ramp signal and the analog pixel signal. In one embodiment, the ADC 1400 may convert a correlated double sampling signal generated by the correlated double sampler 1300 for each column into a digital signal and output the digital signal.

The ADC 1400 may include a plurality of column counters respectively corresponding to the columns of the pixel array 1100. Each column of the pixel array 1100 is connected to each column counter, and image data may be generated by converting a correlated double sampling signal corresponding to each column into a digital signal using the column counters. In another embodiment, the ADC 1400 may include one global counter and convert a correlated double sampling signal corresponding to each column into a digital signal using a global code provided by the global counter.

The output buffer 1500 may temporarily hold and output image data per each column provided from the ADC 1400. The output buffer 1500 may temporarily store image data output from the ADC 1400 based on a control signal from the timing controller 1700. The output buffer 1500 may operate as an interface that compensates for a difference in transmission (or processing) speed between the image sensing device and other devices connected to the image sensing device.

The column driver 1600 may select a column of the output buffer 1500 based on a control signal from the timing controller 1700 and perform control operations such that pieces of image data temporarily stored in the selected columns of the output buffer 1500 are sequentially output. In an embodiment, the column driver 1600 may receive an address signal from the timing controller 1700, and the column driver 1600 may select a column of the output buffer 1500 by generating a column selection signal based on the address signal to perform control such that the image data is output from the selected column of the output buffer 1500 to the outside.

The timing controller 1700 may control at least one of the row driver 1200, the correlated double sampler 1300, the ADC 1400, the output buffer 1500, the column driver 1600, and the bias generator 1800.

The timing controller 1700 may provide a clock signal required for operation of each component of the image sensing device, a control signal for timing control, address signals for selecting a row or column, a signal for controlling a level of a bias voltage applied to the pixel array 1100, or others to at least one of the row driver 1200, the correlated double sampler 1300, the ADC 1400, the output buffer 1500, the column driver 1600 and the bias generator 1800. In an embodiment, the timing controller 1700 may include a logic control circuit, a phase lock loop (PLL) circuit, a timing control circuit, and a communication interface circuit, and others.

The bias generator 1800 may generate a bias voltage for suppressing dark current generated in pixels of the pixel array 1100 and supply the generated bias voltage to the pixel array 1100.

The bias voltage may be determined in a wafer probe test process for the image sensing device and stored in a One-Time Programmable (OTP) memory. For example, the bias voltage may be experimentally determined as a value capable of maximizing a dark current suppression effect while minimizing unnecessary power consumption without deteriorating performance of the image sensing device.

The bias generator 1800 may generate a voltage corresponding to the bias voltage stored in the OTP memory. In an embodiment, the OTP memory may be included in the image sensing device, and in particular, may be included in the bias generator 1800.

In one embodiment, the bias voltage may include a plurality of values.

For example, a plurality of values may respectively correspond to a plurality of operation modes of the image sensing device. A dark current generated under low-light conditions may be different from a dark current generated under high-light conditions, and a bias voltage provided by the bias generator 1800 to effectively suppress dark current in each environment may vary depending on modes.

Alternatively, a plurality of values may respectively correspond to a plurality of regions of the pixel array 1100. The generated dark current may be different according to the positions of pixels on the pixel array 1100, and the bias voltage provided by the bias generator 1800 to effectively suppress the dark current regardless of the position of the pixel may vary depending on the regions of the pixel array 1100.

The bias voltage may be a negative voltage having a negative sign, but the scope of the disclosed technology is not limited thereto.

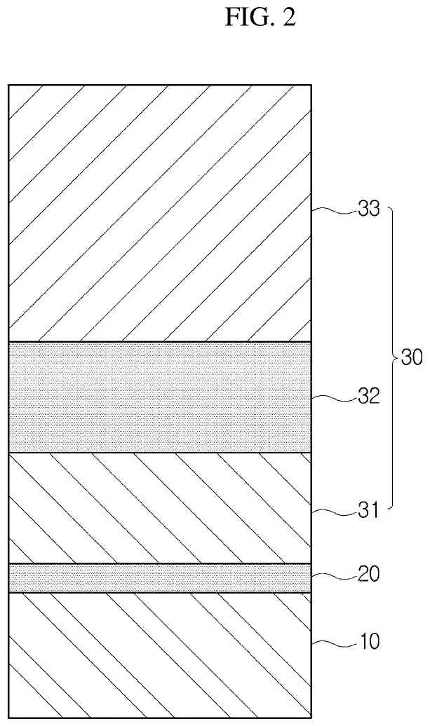

FIG. 2 illustrates an example of a portion of a layered structure of pixels included in the pixel array shown in FIG. 1.

Referring to FIG. 2, an image sensing device based on an embodiment may include a substrate 10, a first dielectric layer 20, and a field effect passivation layer 30.

The substrate 10 may include a semiconductor substrate. The semiconductor substrate may be in a single crystal state and may include a silicon-containing material. That is, the substrate 10 may include a single crystal silicon-containing material.

The substrate 10 may be a substrate thinned through a thinning process. For example, the substrate 10 may be a bulk silicon substrate thinned through the thinning process. The substrate 10 may include P-type impurities.

The first dielectric layer 20 is formed over the substrate 10 and may include SiO2.

The field effect passivation layer 30 (FEP) may be formed over the first dielectric layer 20 to reduce the surface recombination of carriers in order to reduce the undesired dark current and to improve the imaging sensing performance. In some implementations, the field effect passivation (FEP) can be achieved by establishing a surface electric field that repels one type of carriers and therefore limits the amount of undesired surface recombination of the carriers at the interface.

In some embodiments of the disclosed technology, the field effect passivation layer 30 may include a first high-k dielectric layer 31, a second dielectric layer 32, and a second high-k dielectric layer 33.

In some implementations, the first high-k dielectric layer 31 may be formed over the first dielectric layer 20 and may include a dielectric material having a high dielectric constant (High-k). In one example, the high dielectric constant may include a dielectric constant that is higher thana dielectric constant of the first dielectric layer 20.

In some implementations, the first high-k dielectric layer 31 may include Al2O3.

In some implementations, the second dielectric layer 32 may be formed between the first high-k dielectric layer 31 and the second high-k dielectric layer 33.

In some implementations, the second dielectric layer 32 may include SiO2.

In some implementations, the second high-k dielectric layer 33 may be formed over the second dielectric layer 32 and may include a dielectric material having a high dielectric constant (High-k). In one example, the high dielectric constant may include a dielectric constant that is higher thana dielectric constant of the first dielectric layer 20.

In some implementations, the second high-k dielectric layer 33 may include HfO2.

In some implementations, the substrate 10, the first dielectric layer 20, the first high-k dielectric layer 31, the second dielectric layer 32, and the second high-k dielectric layer 33 may be sequentially stacked in the order thereof.

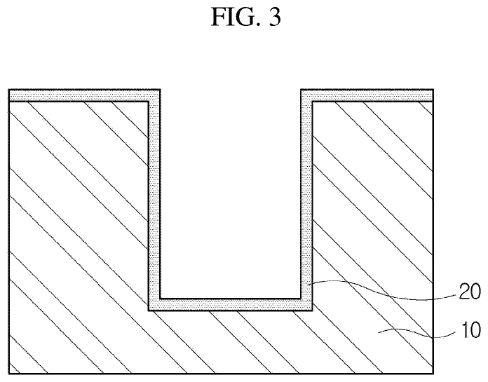

FIGS. 3 to 6 show a process of forming the stacked structure of FIG. 2.

Referring to FIG. 3, the first dielectric layer 20 may be formed over the substrate 10.

In some implementations, the first dielectric layer 20 may include SiO2 and may have a thickness of 20 Å to 100 Å.

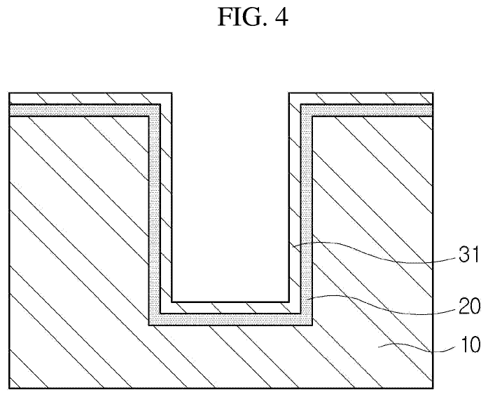

Referring to FIG. 4, the first high-k dielectric layer 31 may be formed over the first dielectric layer 20.

In some implementations, the first high-k dielectric layer 31 may include a dielectric material having a high dielectric constant (High-k). In one example, the high dielectric constant may include a dielectric constant that is higher thana dielectric constant of the first dielectric layer 20. In some implementations, the first high-k dielectric layer 31 may include Al2O3.

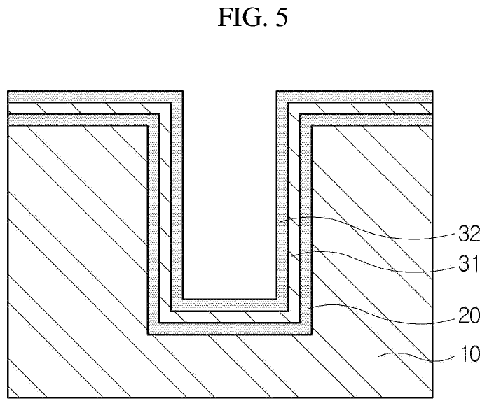

Referring to FIG. 5, the second dielectric layer 32 may be formed over the first high-k dielectric layer 31.

In some implementations, the second dielectric layer 32 may include SiO2 and may have a thickness of 20 Å to 100 Å.

When the thickness of SiO2 is thin, the dipole effect is reduced, and on the contrary, when the thickness of SiO2 is thick, the distance between high dielectric constant (high-k) materials is increased to reduce the field effect, so that the thickness of the first dielectric layer 20 and the thickness of the second dielectric layer 32 may be optimally determined in a range of 20 Å to 100 Å.

The first dielectric layer 20 and the second dielectric layer 32 may be deposited in a low temperature (e.g., less than 450° C.) method which does not affect materials included in the first high-k dielectric layer 31 and the second high-k dielectric layer 33. However, in some implementations, it is preferable to exclude a plasma method that may cause electric charge damage to the surface of the substrate 10 or materials included in the first high-k dielectric layer 31 and the second high-k dielectric layer 33.

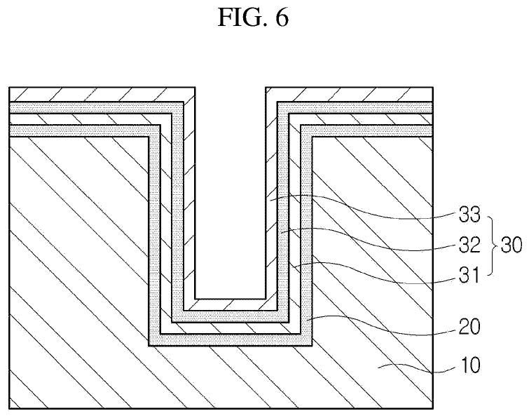

Referring to FIG. 6, the second high-k dielectric layer 33 may be formed over the second dielectric layer 32.

The second high-k dielectric layer 33 may include a dielectric material having a high dielectric constant (High-k). In one example, the high dielectric constant may include a dielectric constant that is higher than a dielectric constant of the first dielectric layer 20. The second high-k dielectric layer 33 may include HfO2, as an example.

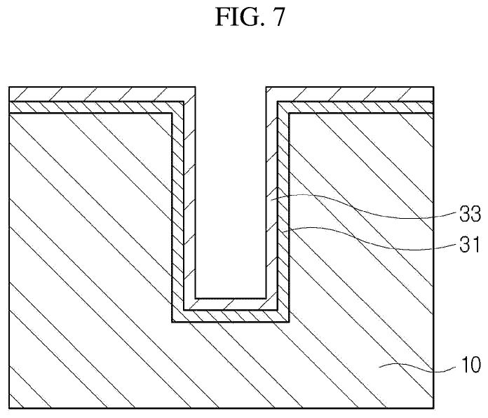

FIG. 7 illustrates an example of a portion of a layered structure of pixels included in the pixel array shown in FIG. 1.

Referring to FIG. 7, when only the first high-k dielectric layer 31 is formed over the substrate 10 without the first dielectric layer 20, the positive charge effect of octahedrally Al3+ may be exhibited.

On the other hand, when the first dielectric layer 20 exists over the substrate 10, the tetrahedrally atomic order of AlO4− is caused at the interface between the first dielectric layer 20 and the first high-k dielectric layer 31, exhibiting a negative charge effect.

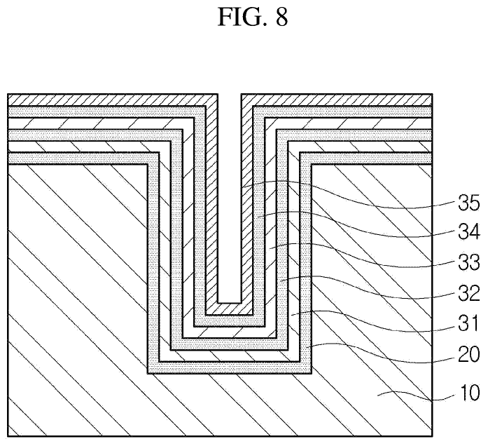

FIG. 8 illustrates an example of a portion of a layered structure of pixels included in the pixel array shown in FIG. 1.

Referring to FIG. 8, an image sensing device based on an embodiment may include a substrate 10, a first dielectric layer 20, a first high-k dielectric layer 31, a second dielectric layer 32, a second high-k dielectric layer 33, a third insulating layer 34 and a third dielectric layer 35.

In some implementations, the first dielectric layer 20, the second dielectric layer 32, and the third insulating layer 34 may include SiO2.

In some implementations, the first high-k dielectric layer 31, the second high-k dielectric layer 33, and the third dielectric layer 35 may include a dielectric material having a high dielectric constant (High-k). In one example, the high dielectric constant may include a dielectric constant that is higher than a dielectric constant of the first dielectric layer 20.

In some implementations, the first high-k dielectric layer 31 may include Al2O3.

In some implementations, the second high-k dielectric layer 33 may include HfO2.

In some implementations, the third dielectric layer 35 may include ZrO2.

In some implementations, the thickness of the first dielectric layer 20, the second dielectric layer 32, and the third insulating layer 34 may be in a range of 20 Å to 100 Å.

In some implementations, the image sensing device may include a plurality of dielectric layers having a high dielectric constant (high-k) and a plurality of insulating layers formed between the dielectric layers having a high dielectric constant (high-k). The field effect passivation (FEP) may be strengthened by maximizing the electric field of the dipole through the strong coupling between the dielectric layer having the high dielectric constant (high-k) and the SiO2 insulating layer to effectively control the dark characteristics.

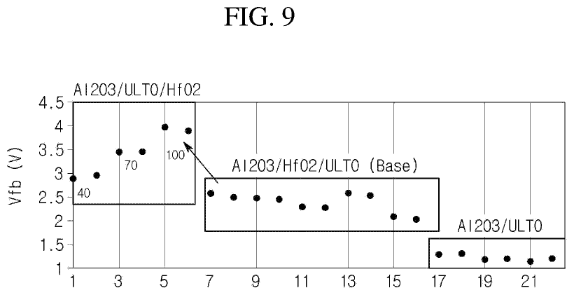

FIG. 9 is a diagram showing rectangular areas each including Vfb measurement values for each film stack.

Referring to FIG. 9, dipole layers are formed between the first dielectric layer 20 and the first high-k dielectric layer 31, between the first high-k dielectric layer 31 and the second dielectric layer 32, and between the second dielectric layer 32 and the second high-k dielectric layer 33, so that the FEP characteristics may be strengthened, and accordingly, the effect of controlling the dark characteristics may be improved.

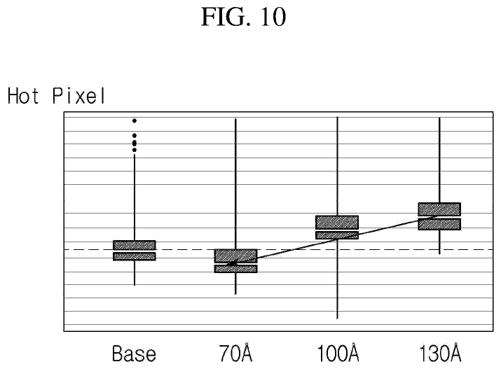

FIG. 10 is a diagram showing a hot pixel reduction effect based on an embodiment.

Referring to FIG. 10, an effect of reducing hot pixels may be achieved through the first dielectric layer 20 formed between the substrate 10 and the first high-k dielectric layer 31 and the second dielectric layer 32 formed between the first high-k dielectric layer 31 and the second high-k dielectric layer 33, compared to a structure that does not include the first dielectric layer 20 and the second dielectric layer 32.

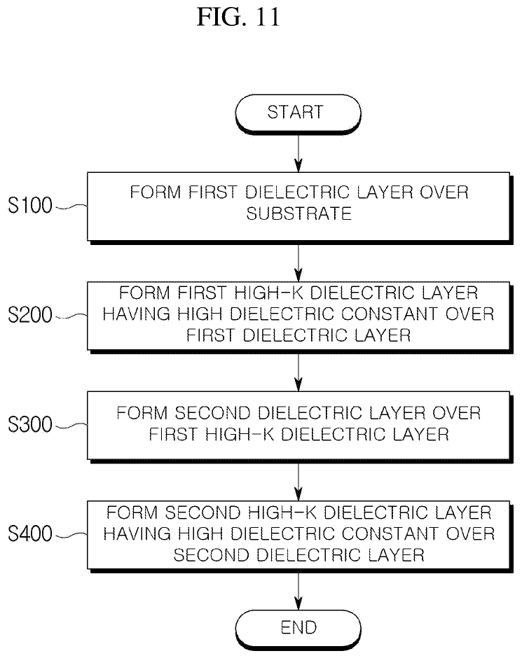

FIG. 11 is a flowchart of a method of manufacturing an image sensing device including the stacked structure of FIG. 2.

Referring to FIG. 11, a method of manufacturing an image sensing device based on an embodiment may include forming a first dielectric layer 20 over a substrate 10 (S100), forming a first high-k dielectric layer 31 having a first dielectric constant higher than a dielectric constant of the first dielectric layer 20 over the first dielectric layer 20 (S200), forming a second dielectric layer 32 over the first high-k dielectric layer 31 (S300), and forming a second high-k dielectric layer 33 having a second dielectric constant higher than the dielectric constant of the first dielectric layer 20 over the second dielectric layer 32 (S400).

Operations S100 to S400 are the same as processes of forming the image sensing device described above, and thus detailed descriptions thereof are omitted.

As discussed above, the disclosed technology can be implemented in some embodiments to provide an image sensing device (e.g., CIS device) that can secure hot pixel characteristics and dark characteristics using the Field Effect Passivation (FEP) effect on the Si surface that is achieved using a high dielectric constant (high-k) material, improving characteristics of the image sensing device.

Since a dipole layer is formed between a high dielectric constant dielectric layer and an insulating layer, field effect passivation (FEP) characteristics are enhanced, thus improving the effect of controlling dark characteristics.

Although the embodiments of the disclosed technology have been described in detail above, the scope of the disclosed technology is not limited thereto, and various modifications and improvements made by those skilled in the art using the basic concept of the disclosed technology defined in the following claims are also included in the scope of the disclosed technology.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples are described and other implementations, enhancements and variations can be made based on what is described and illustrated in this patent document.

What is claimed is:

1. An image sensing device comprising:
a substrate;
a first dielectric layer formed over the substrate; and
a field effect passivation layer formed over the first dielectric layer.

2. The image sensing device of claim 1, wherein the field effect passivation layer comprises:
a first high-k dielectric layer formed over the first dielectric layer and having a first dielectric constant higher thana dielectric constant of the first dielectric layer;
a second high-k dielectric layer having a second dielectric constant higher than the dielectric constant of the first dielectric layer; and
a second dielectric layer formed between the first high-k dielectric layer and the second high-k dielectric layer.

3. The image sensing device of claim 1, wherein the first dielectric layer includes SiO₂.

4. The image sensing device of claim 2, wherein the first high-k dielectric layer includes Al₂O₃.

5. The image sensing device of claim 2, wherein the second high-k dielectric layer includes HfO₂.

6. The image sensing device of claim 2, wherein the second dielectric layer includes SiO₂.

7. The image sensing device of claim 2, wherein each of the first dielectric layer and the second dielectric layer has a thickness ranging from 20 Å to 100 Å.

8. An image sensing device comprising:
a substrate;
a first dielectric layer formed over the substrate;
a first high-k dielectric layer formed over the first dielectric layer and having a first dielectric constant higher thana dielectric constant of the first dielectric layer;
a second dielectric layer formed over the first high-k dielectric layer;
a second high-k dielectric layer formed over the second dielectric layer and having a second dielectric constant higher than the dielectric constant of the first dielectric layer;
a third insulating layer formed over the second high-k dielectric layer; and
a third dielectric layer formed on the third insulating layer and having a third dielectric constant higher than a reference dielectric constant.

9. The image sensing device of claim 8, wherein each of the first dielectric layer, the second dielectric layer, and the third insulating layer includes SiO₂.

10. The image sensing device of claim 9, wherein the first high-k dielectric layer includes Al₂O₃.

11. The image sensing device of claim 9, wherein the second high-k dielectric layer includes HfO₂.

12. The image sensing device of claim 9, wherein the third dielectric layer includes ZrO₂.

13. The image sensing device of claim 9, wherein each of the first dielectric layer, the second dielectric layer, and the third insulating layer have a thickness ranging from 20 Å to 100 Å.

14. A method of manufacturing an image sensing device, comprising:
forming a first dielectric layer over a substrate;
forming a first high-k dielectric layer having a first dielectric constant higher than a dielectric constant of the first dielectric layer over the first dielectric layer;
forming a second dielectric layer over the first high-k dielectric layer; and
forming a second high-k dielectric layer having a second dielectric constant higher than the dielectric constant of the first dielectric layer over the second dielectric layer.

15. The method of claim 14, wherein each of the first dielectric layer and the second dielectric layer include SiO₂.

16. The method of claim 14, wherein the first high-k dielectric layer includes Al₂O₃.

17. The method of claim 14, wherein the second high-k dielectric layer includes HfO₂.
